(19) United States
(12) Patent Application Publication
(10) Pub. No.: US 2010/0188884 A1
(43) Pub. Date: Jul. 29, 2010

(54) NONVOLATILE MEMORY ELEMENT, NONVOLATILE MEMORY APPARATUS, AND METHOD OF WRITING DATA TO NONVOLATILE MEMORY ELEMENT

(76) Inventors: Satoru Mitani, Osaka (JP); Yoshihiko Kanzawa, Osaka (JP); Koji Katayama, Osaka (JP); Zhiqiang Wei, Osaka (JP); Takeshi Takagi, Osaka (JP)

Correspondence Address: MCDERMOTT WILL & EMERY LLP, 600 13TH STREET, NW, WASHINGTON, DC, 20005-3096, US

(21) Appl. No.: 12/667,856

(22) PCT Filed: Apr. 13, 2009
(86) PCT No.: PCT/JP2009/001682

§ 371 Date: Jan. 5, 2010

(30) Foreign Application Priority Data
May 8, 2008 (JP) 2008-121947

(51) Int. Cl. G11C 11/00; H01L 45/00

(52) U.S. Cl. 365/148; 257/4; 257/E45.001

(57) ABSTRACT

A nonvolatile memory element comprises a first electrode (503), a second electrode (505), and a resistance variable layer (504) disposed between the first electrode and the second electrode, a resistance value between the first electrode and the second electrode being switchable reversibly in response to positive and negative electric signals applied between the first electrode and the second electrode; wherein the resistance variable layer includes an oxygen-deficient hafnium oxide; wherein the first electrode and the second electrode comprise elements which are different from each other; and wherein a standard electrode potential V1 of an element forming the first electrode, a standard electrode potential V2 of an element forming the second electrode and a standard electrode potential V0 of hafnium satisfy a relationship of V1<V2 and V0<V2.

### TECHNICAL FIELD

The present invention relates to a nonvolatile memory element. More particularly, the present invention relates to a resistance variable nonvolatile memory element whose resistance value is switchable in response to an electric signal applied, a nonvolatile memory apparatus, and a method of writing data to a nonvolatile memory element.

### BACKGROUND ART

With recent advancement of digital technologies, electronic hardware such as portable information devices and home information appliances have been developed to provide higher functionality. For this reason, demands for an increase in a capacity of a nonvolatile memory element, reduction in a write electric power in the memory element, reduction in write/read time in the memory element, and longer life of the memory element have been increasing.

In response to such demands, it is said that there is a limitation on miniaturization of the existing flash memory using a floating gate. Accordingly, in recent years, a novel resistance variable nonvolatile memory element using a resistance variable layer as a material of a memory portion has attracted an attention.

As shown in FIG. 17, the resistance variable nonvolatile memory element basically has a very simple structure in which a resistance variable layer 1702 is sandwiched between a lower electrode 1701 and an upper electrode 1703. Upon application of a predetermined electric pulse having a voltage of a magnitude which is not smaller than a threshold between the upper and lower electrodes, the nonvolatile memory element switches to a high-resistance state or to a low-resistance state. By corresponding these different resistance states to numeric values, respectively, data is stored. Because of such a simple structure and operation, further miniaturization and cost reduction of the resistance variable nonvolatile memory element are expected. Since switching to the high-resistance state or to the low-resistance state occurs in an order of 100 ns or less, the resistance variable nonvolatile memory element has attracted an attention to achieve a high-speed operation, and a variety of proposals have been proposed.

For example, Patent document 1 discloses a resistance variable nonvolatile memory element in which metal ions are caused to travel into and out of a resistance variable layer 1702 to attain a high-resistance state and a low-resistance state by applying a voltage to an upper electrode and to a lower electrode, thereby storing data. Also, as disclosed in Patent document 2, there is known a resistance variable memory in which a crystalline state of a resistance variable layer is changed using an electric pulse to switch its resistance state.

In addition to the above, there are numerous proposals for resistance variable nonvolatile memory elements using metal oxides for the resistance variable layer 1702. The resistance variable nonvolatile memory elements using the metal oxides are classified into two major kinds depending on the material used for the resistance variable layer. Patent document 3 or the like discloses one kind of resistance variable nonvolatile memory element using perovskite materials (Pr₍₁₋ₓ₎CaXMnO₃ (PCMO), LaSrMnO₃ (LSMO), GdBaCoₓO_{y} (GBCO), etc) as the resistance variable layer.

The other kind is resistance variable nonvolatile memory elements using binary transition metal oxides. Since the binary transition metal oxides have a very simple composition as compared to the above illustrated perovskite materials, composition control and layer deposition in manufacturing arc relatively easy. In addition, the binary transition metal oxides have an advantage that they are relatively highly compatible with a semiconductor manufacturing process. For these reasons, the binary transition metal oxides have been recently vigorously developed.

Patent document 4 discloses NiO, V₂O₅, ZnO, Nb₂O₅, TiO₂, WO₃, and CoO as the resistance variable material, for example. Patent document 5 or Non-patent documents 1 to 3 disclose resistance variable elements using transition metal oxides, which are in particular, oxides which are oxygen-deficient in stoichiometric composition (hereinafter referred to as oxygen-deficient oxides) such as oxides of transition metals of Ni, Nb, Ti, Zr, Hf, Co, Fe, Cu, and Cr, as the resistance variable material.

The oxygen-deficient oxide will be described in greater detail. For example, in the case of Ni, NiO is known as an oxide having a stoichiometric composition. NiO contains O atoms and Ni atoms which are equal in number, and its oxygen content rate is 50 at %. An oxide with an oxygen content rate lower than 50 at % is referred to as the oxygen-deficient oxide. In this example, since the oxide is Ni oxide, it may be referred to as an oxygen-deficient Ni oxide.

Patent document 6 and Non-patent document 2 disclose an example in which a structure in which a surface of titanium nitride is oxidized to form a titanium oxide (TiO₂) crystalline film of a nanometric order is used as a resistance variable layer.

The nonvolatile memory elements using the above mentioned metal oxides are classified into two kinds, depending on how resistance switching occurs. One kind is a unipolar nonvolatile memory element which switches resistance in response to electric pulses having the same polarity and different-magnitude voltages (e.g., increases and decreases a resistance value in response to voltages of +1V and +2V applied). The nonvolatile memory elements disclosed in Patent documents 4 and 5 are unipolar nonvolatile memory elements. The other kind is a bipolar nonvolatile memory element which is controlled to switch resistance in response to electric pulses having voltages of different polarities (e.g., increases and decreases a resistance value in response to voltages of +1V and −1V applied). Such nonvolatile memory elements are disclosed in Patent document 3 and Patent document 6.

As the upper and lower electrode materials sandwiching the resistance variable layer, for example, Patent document 5 discloses iridium (a), platinum (Pt), ruthenium (Ru), tungsten (W), Ir oxide, Ru oxide, titanium (Ti) nitride, polysilicon, etc. Patent document 6 discloses nonvolatile memory elements using as electrode materials Pt, Ir, osmium (Os), Ru, rhodium (Rh), palladium (Pd), Ti, cobalt (Co), W, etc. Patent document 7 discloses nickel (Ni), silver (Ag), gold (Au), and Pt. Patent document 8 discloses Pt, Ir, Ru, Ir oxide, and Ru oxide.

Patent document 1: Japanese Laid-Open Patent Application Publication No. 2006-40946.
Patent document 2: Japanese Laid-Open Patent Application Publication No. 2004-349689.
Patent document 3: U.S. Pat. No. 6,473,332 Specification
Patent document 4: Japanese Laid-Open Patent Application Publication No. 2004-363604.
Patent document 5: Japanese Laid-Open Patent Application Publication No. 2005-317976.
Patent document 6: Japanese Laid-Open Patent Application Publication No. 2007-180202
Patent document 7: Japanese Laid-Open Patent Application Publication No. 2007-88349
Patent document 8: Japanese Laid-Open Patent Application Publication No. 2006-324447
Non-patent document 1: I.G. Beak et al., Tech. Digest IEDM 2004, page 587
Non-patent document 2: Japanese Journal of Applied Physics Vol 45, No 11, 2006, ppL310-L312
Non-patent document 3: A. Chen et al., Tech. Digest IEDM 2005, page 746

### DISCLOSURE OF THE INVENTION

### Problem to be Solved by the Invention

However, data relating to controllability or the like of a resistance variable phenomenon depending on a combination of the upper and lower electrode materials has not been disclosed so far. Indeed, Patent documents 5 to 8 disclose candidates of the electrodes which possibly easily attain resistance switching in the resistance variable nonvolatile memory elements as described above. However, Patent documents 5 and 8 do not disclose a combination of upper and lower electrode materials which are suitable to cause resistance switching with high controllability when a memory apparatus incorporating resistance variable nonvolatile memory elements is manufactured.

Inventors manufactured nonvolatile memory elements without considering a combination of the materials suitable for use as the upper and lower electrodes and investigated their electric characteristics. Manufactured was an element having a basic structure of FIG. 17 and a vertically symmetric structure, in which a resistance variable layer 1702 made of oxygen-deficient Hf oxide is sandwiched between a lower electrode 1701 made of Pt and an upper electrode 1703 made of Pt. The oxygen content rate of the oxygen-deficient Hf oxide of the resistance variable layer 1702 was set to 56.8 at % (x is 1.31 when the oxygen-deficient Hf oxide is expressed as HfOₓ). Hereinafter, this nonvolatile memory element is referred to as element A. The relationship between names of the element and the electrode materials are all illustrated in table 2, including elements described in Embodiments below.

FIG. 14 shows resistance switching which occurs when an electric pulse was applied to the element A. In FIGS. 14(a) and 14(b), a horizontal axis indicates the number of electric pulses applied between the lower electrode 1701 and the upper electrode 1703, and a vertical axis indicates a resistance value.

FIG. 14(a) shows resistance measurement result of the resistance between the lower electrode 1701 and the upper electrode 1703 which is obtained when electric pulses having voltages of +1.5V and −1.2V were applied with a pulse width 100 nsec alternately to the upper electrode 1703 on the basis of the lower electrode 1701. In this case, the resistance value switched to about 500˜700Ω by applying the electric pulse of the voltage of +1.5V, and switched to about 140Ω by applying the electric pulse of the voltage of −1.2V. That is, the element A switched to a high-resistance state when the upper electrode 1703 was applied with an electric pulse of a voltage higher than a voltage of the electric pulse applied to the lower electrode 1701.

FIG. 14(b) shows a result in a case where a balance of the voltage applied was changed and a negative voltage was made larger. In this case, electric pulses of voltages of −1.5V and +1.2V were applied to the upper electrode 1703 on the basis of the lower electrode 1701. So, the element A switched to the high-resistance state and the resistance value became about 900˜1200Ω when the electric pulse of −1.5V was applied to the element A, while the element A switched to the low-resistance state and the resistance value became about 150Ω when the electric pulse of +1.2V was applied to the element A. That is, the element A switched to a low-resistance state when the upper electrode 1703 was applied with an electric pulse of a voltage higher than a voltage of the electric pulse applied to the lower electrode 1701. That is, the measurement result of FIG. 14(b) indicates that the operation corresponding to the measurement result of FIG. 14(a) is reversed.

The above described results imply that the operation of the element A is very inappropriate as the operation of the bipolar nonvolatile memory element. The bipolar nonvolatile memory element has a feature that resistance switching is not controlled by the magnitude of the voltage of the electric pulse applied but resistance is controlled using the electric pulses having voltages with different polarities. In other words, the bipolar element has a feature that directionality of resistance switching (directionality of switching from a high-resistance state to a low-resistance state or from the low-resistance state to the high-resistance state) does not vary even when the magnitude of the voltage applied to the element varies to a certain extent or the voltage of the threshold causing resistance switching varies due to some factors such as a variation in manufacturing, etc. However, in the case of the element A, the resistance value increased or decreased when the positive voltage was applied to the upper electrode. Thus, the element A has a problem that the resistance value is not determined uniquely according to the polarity of the voltage applied to the electrode.

In order to seek a cause of two-mode resistance switching of the nonvolatile memory element according to the polarity of the applied voltage, the inventors researched which portion of the nonvolatile memory element causes resistance switching. To this end, an element B was manufactured. In the present case, illustrated is a result obtained using oxygen-deficient Ta oxide which is regarded as operating in a similar mechanism to that of Hf. FIG. 15 shows a schematic view of the cross-section of the element B. As shown in FIG. 15, two electrodes made of Pt were formed at each of the upper and lower sides of an oxygen-deficient Ta oxide layer 205 of 100 nm, i.e., four electrodes 201, 202, 203, and 204 in total were formed. Then, the voltages of +2.0V and −1.5V were applied with a pulse width of 100 nsec to the electrode 201 on the basis of the electrode 202. The element B switched to a high-resistance state when an electric pulse of the voltage of +2.0V was applied to the element B and switched to a low-resistance state when an electric pulse of the voltage of −1.5V was applied to the element B. The resistance values were measured among the four electrodes under the condition in which the resistance between the electrode 201 and the electrode 202 was switched in this way. To be specific, +2.0V was applied between the electrode 201 and the electrode 202 to switch resistance between the electrode 201 and the electrode 202 to a high-resistance state, and under this condition, the resistance value between the electrode 201 and the electrode 203, the resistance value between the electrode 201 and the electrode 204, the resistance value between the electrode 202 and the electrode 203, the resistance value between the electrode 202 and the electrode 204, and the resistance value between the electrode 203 and the electrode 204 were respectively measured. Then, −1.5V was applied between the electrode 201 and the electrode 202 to switch resistance between the electrode 201 and the electrode 202 to a low-resistance state, and under this condition, the resistance values between the electrodes were measured as in the above described manner.

The above-mentioned measurement was repeated 10 times and the resulting resistance values between the electrodes are illustrated in table 1.

TABLE 1

| | |
|---|---|
| Resistance value | Resistance value |
| (Ω) generated | (Ω) generated |
| by applying | by applying |
| +2.0 V between | −1.5 V between |
| electrodes | electrodes |
| 201 and 202 | 201 and 202 |

| | | |
|---|---|---|
| Between electrodes 201 and | 546 | 262 |
| 202 | | |
| Between electrodes 201 and | 1351 | 1276 |
| 203 | | |
| Between electrodes 201 and | 1075 | 828 |
| 204 | | |
| Between electrodes 202 and | 1153 | 1153 |
| 203 | | |
| Between electrodes 202 and | 704 | 704 |
| 204 | | |
| Between electrodes 203 and | 698 | 698 |
| 204 | | |

The result was such that switching of the resistance value between the electrode 201 and the associated portions was observed and the resistance values between the portions which are not associated with the electrode 201 did not substantially change. From this fact, it is found that resistance switching occurred in response to the voltage applied between the electrode 201 and the electrode 202 only in the region the vicinity of the electrode 201.

From the above result, in the resistance variable element using the oxygen-deficient Ta oxide as the resistance variable layer, resistance switching occurs only in a region near the electrode in the oxygen-deficient Ta oxide layer. Also, it is considered that resistance switching occurs in the region in the vicinity of the electrode at a high potential side, when the element switches to the high-resistance (in this case, a voltage with a higher potential is applied to the electrode 201 with respect to the electrode 202 when the element switches to the high-resistance state).

It is considered that the same phenomenon occurs in the case of using the oxygen-deficient Hf oxide of transition metal. This is because resistance switching phenomenon caused by an electric field applied to the electrode is observed in the nonvolatile memory element using the Hf oxide layer as the resistance variable layer, as in the case of Ta.

In light of the above result, it is considered that resistance switching occurred in two modes, i.e., a mode (upper electrode mode) in which resistance switching occurred in the vicinity of the interface between the upper electrode 1703 and the oxygen-deficient Hf oxide layer 1702 and a mode (lower electrode mode) in which resistance switching occurred in the vicinity of the interface between the lower electrode 1701 and the oxygen-deficient Hf oxide layer 1702. Considering the polarity of the electric pulse applied and directionality of resistance switching, FIG. 14(a) shows a resistance variable characteristic occurring when the upper electrode mode is a dominant mode, while FIG. 14(b) shows a resistance variable characteristic occurring when the lower electrode mode is a dominant mode. As used herein, a mode in which the element switches to a high-resistance state when a negative voltage is applied to the upper electrode on the basis of the lower electrode and switches to a low-resistance state when a positive voltage is applied to the upper electrode on the basis of the lower electrode is defined as A mode, while a mode in which the element switches to a high-resistance state when a positive voltage is applied to the upper electrode on the basis of the lower electrode and switches to a low-resistance state when a negative voltage is applied to the upper electrode on the basis of the lower electrode is defined as B mode (A mode corresponds to the lower electrode mode and the B mode corresponds to the upper electrode mode.)

From the above results, a structure in which resistance switching occurs in the vicinity of both of the upper and lower electrodes should not be formed in order to attain an ideal bipolar nonvolatile memory element having a structure in which the resistance variable layer is sandwiched between metal electrodes and having a resistance value determined uniquely according to the polarity of the voltage applied to the electrode.

In addition to the above-mentioned problem, there exists a problem that a phenomenon of mixing of the upper electrode mode and the lower electrode mode occurs less frequently when the element is caused to switch resistance repetitively.

FIG. 16 shows a resistance variable characteristic of another element having a structure shown in FIG. 17, which is similar to that of the element A. To be specific, this nonvolatile memory element includes the lower electrode 1701 and the upper electrode 1703 which are made of Pt, and the resistance variable layer 1702 made of an oxygen-deficient Hf oxide (x is 1.6 when the oxygen-deficient Hf oxide is expressed as HfOx) with an oxygen content rate 62 at %. In measurement, the electric pulses of voltages of +2.0V and −1.1V and a pulse width 100 nsec were applied to the upper electrode 1703 on the basis of the lower electrode 1701. As can be seen from FIG. 16, resistance corresponding to a low-resistance state of the element was inconstant when the electric pulses were applied repetitively.

This phenomenon may occur due to the mixing of the upper electrode mode and the lower electrode mode as described above. Since the electric pulses of voltages of +2.0V and −1.1V were applied to the upper electrode 1703 on the basis of the lower electrode 1701, switching between the high-resistance state and the low-resistance state repeated ideally at the upper electrode side of the element. But, in this example, resistance at the lower electrode side also switched, and the entire resistance of the element switched unstably. In other words, it may be considered that a fluctuation in a resistance switching magnitude shown in FIG. 16 may occur, because resistance at the interface between the lower electrode and the oxygen-deficient Hf oxide switched greatly inadvertently.

The above mentioned fluctuation in the resistance switching magnitude is undesirable as the characteristic of the element for storing data based on the magnitude of resistance.

### Means for Solving the Problem

In order to achieve the above described objective, a nonvolatile memory element of the present invention comprises a first electrode, a second electrode, and a resistance variable layer disposed between the first electrode and the second electrode, a resistance value between the first electrode and the second electrode being switchable reversibly in response to positive and negative electric signals applied between the first electrode and the second electrode; wherein the resistance variable layer includes an oxygen-deficient hafnium oxide; wherein the first electrode and the second electrode comprise elements which are different from each other; and wherein a standard electrode potential V1 of an element forming the first electrode, a standard electrode potential V2 of an element forming the second electrode and a standard electrode potential V0 of hafnium satisfy a relationship of V1<V2 and V0<V2.

In a preferred embodiment, to achieve the above described objective, a nonvolatile memory element of the present invention comprises a first electrode, a second electrode, and a resistance variable layer disposed between the first electrode and the second electrode, a resistance value between the first electrode and the second electrode being switchable reversibly in response to positive and negative electric signals applied between the first electrode and the second electrode; wherein the resistance variable layer includes an oxygen-deficient hafnium oxide; wherein the first electrode and the second electrode comprise elements which are different from each other; and wherein a standard electrode potential V1 of an element forming the first electrode, a standard electrode potential V2 of an element forming the second electrode and a standard electrode potential V0 of hafnium satisfy a relationship of V1≦V0<V2.

In a preferred embodiment, the first electrode may be selected from a group consisting of Al, Ti, and Hf and the second electrode is selected from a group consisting of W, Cu, and Pt.

In a preferred embodiment, in a nonvolatile memory element comprising a first electrode, a second electrode, and a resistance variable layer disposed between the first electrode and the second electrode, a resistance value between the first electrode and the second electrode being switchable reversibly in response to electric signals applied between the first electrode and the second electrode, the resistance variable layer includes an oxygen-deficient hafnium oxide; the first electrode and the second electrode comprise elements which are different from each other; and a standard electrode potential V1 of an element forming the first electrode, a standard electrode potential V2 of an element forming the second electrode and a standard electrode potential V0 of hafnium satisfy a relationship of V0<V1<V2.

In a preferred embodiment, the first electrode is made of W and the second electrode is selected from a group consisting of Cu and Pt.

In a preferred embodiment, the oxygen-deficient hafnium oxide is expressed as a chemical formula HfOₓ (0.9≦x≦1.6).

A method of driving the nonvolatile memory element of the present invention is a method of driving the above nonvolatile memory element, wherein the positive and negative electric signals are a positive electric signal with an amplitude V+ which is applied to the second electrode on the basis of the first electrode and a negative electric signal with an amplitude V− which is applied to the second electrode on the basis of the first electrode, and V+ and V− satisfy a relationship of V−<V+; and wherein the resistance value between the first electrode and the second electrode increases in response to the positive electric signal and decreases in response to the negative electric signal.

A nonvolatile memory apparatus of the present invention, comprises the above nonvolatile memory element; and an electric pulse application device; wherein the electric pulse application device is configured to apply the positive and negative electric signals to the nonvolatile memory element to reversibly switch the resistance value between the first electrode and the second electrode of the nonvolatile memory element.

A method of writing data to a nonvolatile memory element of the present invention is a method of writing data to the above nonvolatile memory element, comprises applying the positive and negative electric signals between the first electrode and the second electrode of the nonvolatile memory element to reversibly switch the resistance value between the first electrode and the second electrode of the nonvolatile memory element.

The above and further objects, features and advantages of the present invention will more fully be apparent from the following detailed description of the preferred embodiments with reference to the accompanying drawings.

### EFFECTS OF THE INVENTION

In accordance with the present invention, it is possible to attain a nonvolatile memory element having a reversible and stable rewrite characteristic and a nonvolatile memory apparatus incorporating the nonvolatile memory element.

### BRIEF DESCRIPTION OF THE DRAWINGS

FIG. 1 is a cross-sectional view showing a configuration of a nonvolatile memory element according to an embodiment of the present invention.

FIG. 2 is a view showing the relationship between the resistance value of the nonvolatile memory element and the number of electric pulse applications.

FIG. 3 is a view showing the relationship between the resistance value of the nonvolatile memory element according to the embodiment of the present invention and the number of electric pulse applications.

FIG. 4 is a view showing the relationship between the resistance value of the nonvolatile memory element according to the embodiment of the present invention and the number of electric pulse applications.

FIG. 5 is a view showing the relationship between the resistance value of the nonvolatile memory element according to the embodiment of the present invention and the number of electric pulse applications.

FIG. 6 is a view showing the relationship between the resistance value of the nonvolatile memory element according to the embodiment of the present invention and the number of electric pulse applications.

FIG. 7 is a view showing the relationship between the resistance value of the nonvolatile memory element according to the embodiment of the present invention and the number of electric pulse applications.

FIG. 8 is a view showing the relationship between the resistance value of the nonvolatile memory element according to the embodiment of the present invention and the number of electric pulse applications.

FIG. 9 is a view showing the relationship between the resistance value of the nonvolatile memory element according to the embodiment of the present invention and the number of electric pulse applications.

FIG. 10 is a view showing results of resistance switching in A mode and in B mode.

FIG. 11 is a view showing a mechanism for resistance switching assumed.

FIG. 12 is a view showing a mechanism for resistance switching assumed.

FIG. 13 is a view showing Rutherford backscattering (RBS) analysis result of a composition of a Hf oxide layer manufactured.

FIG. 14 is a view showing the relationship between the resistance value of the nonvolatile memory element and the number of pulse applications.

FIG. 15 is a schematic view of a cross-section of element B.

FIG. 16 is a view showing the relationship between the resistance value of the nonvolatile memory element and the number of pulse applications.

FIG. 17 is a view showing a basic structure of the nonvolatile memory element.

### EXPLANATION OF REFERENCE NUMERALS

200 element B
201, 202, 203, 204 electrodes
205 Ta oxide layer
500 resistance variable element
501 single crystal silicon substrate
502 oxide layer
503, 1501, 1601 upper electrodes
504, 1502, 1602 Hf oxide layer
505, 1503, 1603 lower electrode
506 element region
1504, 1604 oxygen ions

1701 lower electrode layer
1702 resistance variable layer
1703 upper electrode

### BEST MODE FOR CARRYING OUT THE INVENTION

Hereinafter, an embodiment of the present invention will be described with reference to the drawings. In the drawings, the same or corresponding components are designated by the same reference numerals and description thereof will be omitted in some cases.

### Embodiment

As described above, in the resistance variable nonvolatile memory element which uses the oxygen-deficient Hf oxide and performs a bipolar operation, an operation for easily causing resistance switching only in the region in the vicinity of either one of the upper and lower electrodes is desirable. If resistance switching phenomenon depends on the electrode material, it is sufficient to form a structure in which an oxygen-deficient Hf oxide is sandwiched between an electrode material which easily causes resistance switching and an electrode material which does not easily cause resistance switching. In this embodiment, result of research of this will be described.

Prior to explaining the research result, a deposition method of the oxygen-deficient Hf oxide layer, and a suitable range of an oxygen content rate will be described. Then, research result of resistance variable phenomenon in response to the electric pulses of the structure in which the HfOx layer is sandwiched between the electrodes made of Al, Ti, Ta, W, Cu, or Pt will described, to confirm whether or not easiness of resistance switching depends on the electrode material. Finally, measurement result of resistance switching of the resistance variable element having a structure in which the oxygen-deficient Hf oxide is sandwiched between the electrode material which easily causes resistance switching and the electrode material which does not easily cause resistance switching will be described.

[Relationship Between Oxygen Flow Ratio in Sputtering Process and Oxygen Content Rate of Hf Oxide Layer]

Firstly, manufacturing conditions and analysis result of oxygen content rate of the oxygen-deficient Hf oxide layer in this embodiment will be described. The oxygen-deficient Hf oxide layer was deposited by sputtering a Hf target under gas atmosphere of Ar gas and O₂ gas, i.e., reactive sputtering. The deposition method of the oxygen-deficient Hf oxide in this embodiment is as follows.

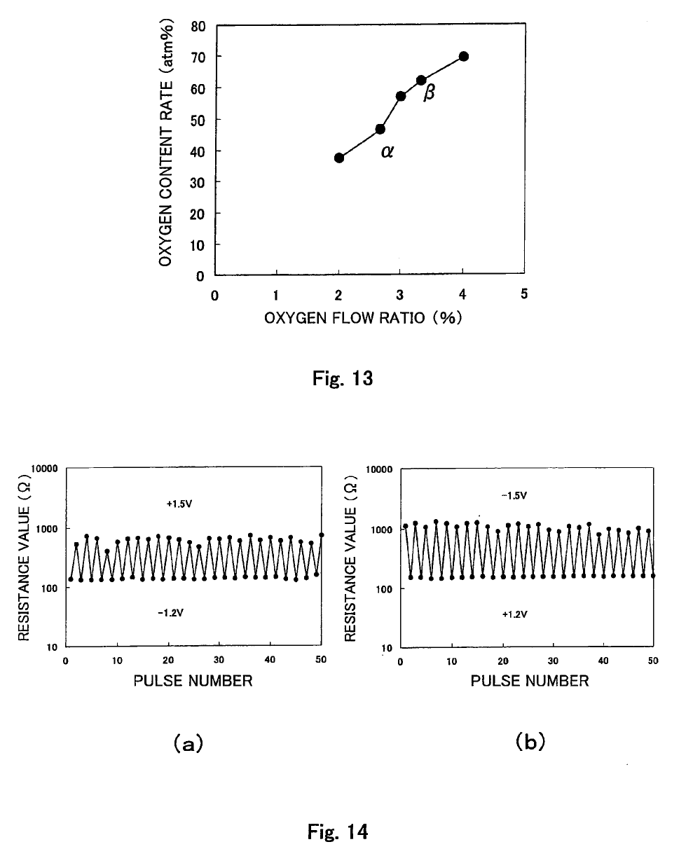

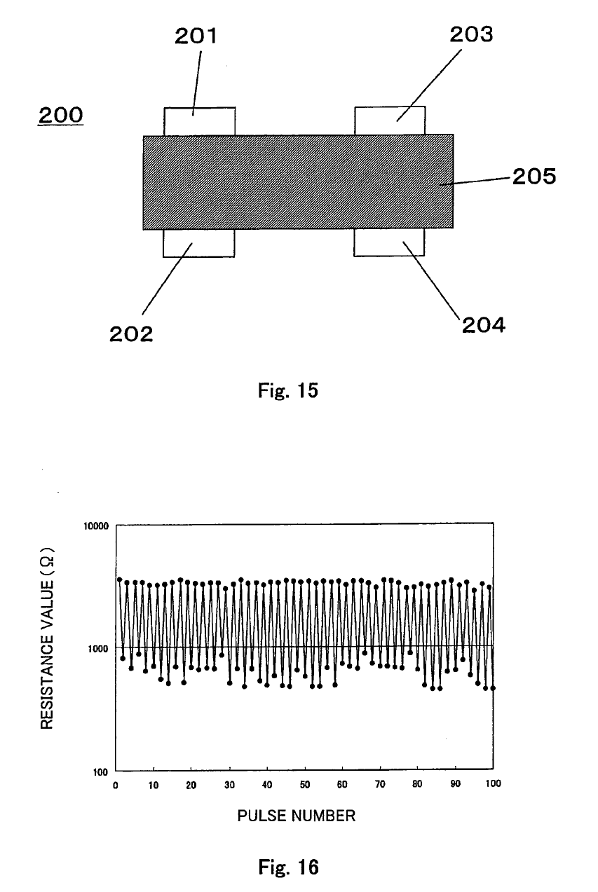

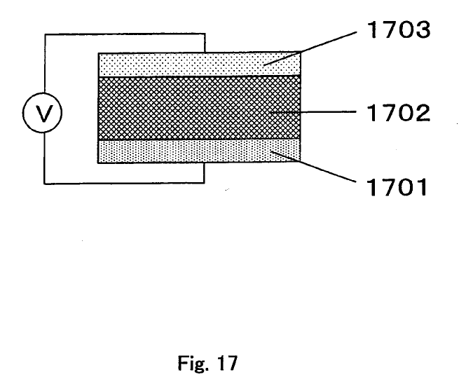

Initially, a substrate was installed within a sputtering device and the sputtering device was evacuated to about 3×10⁻⁵ Pa. Using Hf as a target, sputtering was conducted under the condition in which a power was set to 300 W and a total gas pressure of argon gas and oxygen gas was set to 0.9 Pa and a substrate temperature was set to 30 degrees centigrade. In this case, the flow ratio of the O₂ gas to the Ar gas was changed from 2% to 4.2%. To achieve a primary object which is a composition research, a substrate formed by depositing 200 nm-thick SiO₂ on Si was used and sputtering time was adjusted so that the film thickness of the Hf oxide layer was about 50 nm. FIG. 13 shows Rutherford backscattering (RBS) analysis result of the composition of the Hf oxide layer deposited as described above. As can be seen from FIG. 13, the oxygen content rate of the Hf oxide layer was changed from about 37. 7 at % (HfO_{0.6}) to about 69.4 at % (HfO_{2.3}) when the oxygen flow ratio was changed from 2% to 4.2%. From the above result, it was revealed that the oxygen content rate of the Hf oxide layer can be controlled by the oxygen flow ratio, and an oxygen-deficient Hf oxide in which oxygen is deficient with respect to the oxygen content rate 66.7 at % of HfO₂ (HfO₂) which is a stoichiometric oxide of Hf to a Hf oxide regarded as containing excess oxygen were deposited.

Although in this embodiment, the Rutherford backscattering (RBS) was used for analysis of the Hf oxide layer, instrument analysis method such as Auger electron spectroscopy (AES), fluorescent X-ray analysis (XPS), or electrons probe micro analysis (EPMA) may be used.

[Resistance Variable Characteristic of Oxygen-Deficient Hf Oxide Layer]

Research was made to confirm an oxygen content rate of the oxygen-deficient Hf oxide which exhibits resistance switching, among the oxygen-deficient Hf oxides manufactured as described above. In this case, Pt was used as the upper and lower electrodes sandwiching the oxygen-deficient Hf oxide layer. The nonvolatile element using Pt as the upper and lower electrodes is improper as the bipolar resistance variable nonvolatile element as described above. However, Pt is an electrode material which causes resistance switching very easily as described later and is an optimal material to determine whether or not an oxygen-deficient Hf oxide having a certain oxygen content rate exhibits resistance switching.

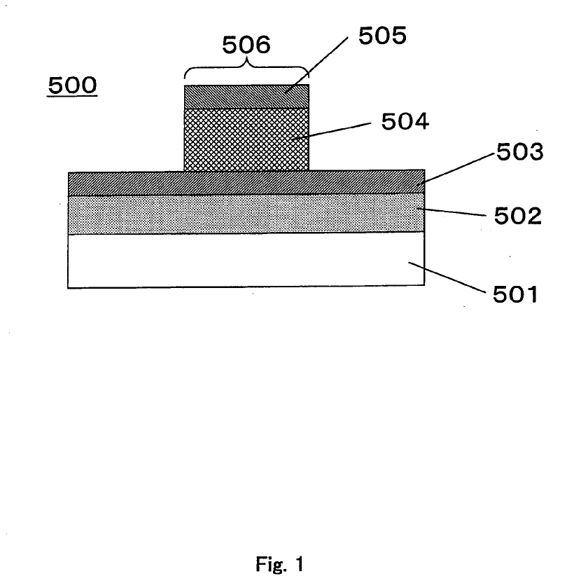

For the above explained reasons, a nonvolatile memory element 500 shown in FIG. 1 was manufactured. To be specific, on a single-crystal silicon substrate 501, 200 nm-thick oxide layer 502 was formed by a thermal oxidation process, and a 100 nm-thick Pt thin layer was deposited on an oxide layer 502 as a lower electrode layer 503 by a sputtering process. Then, using Hf as a target, an oxygen-deficient Hf oxide layer 504 was deposited by a reactive sputtering process. The nonvolatile memory element was manufactured by changing the flow ratio of the oxygen gas from 2% to 4.2% which is the range researched in this embodiment, as in the above samples analyzed. The film thickness of the oxygen-deficient Hf oxide layer 504 was set to 30 nm.

Then, a 150 nm-thick Pt thin layer was deposited on the oxygen-deficient Hf oxide layer 504 as an upper electrode layer 505, by the sputtering process.

Finally, by a photolithography process and a dry etching process, an element region 506 was formed. The element region 506 has a circular pattern of a 3 μm diameter.

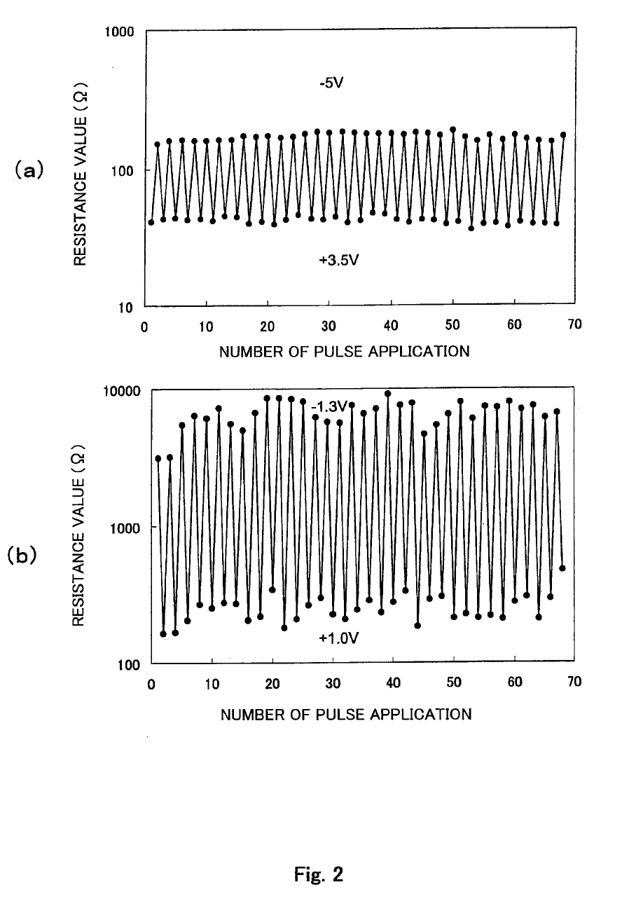

The resistance variable phenomenon of the nonvolatile memory element manufactured as described above was measured. As a result, in the nonvolatile memory element using the Hf oxide layer at the point α (oxygen flow ratio: about 2.7%, oxygen content rate: about 46.6 at %) to the nonvolatile memory element using the Hf oxide layer at point β (oxygen flow ratio: about 3.3%, oxygen content rate: about 62 at %), the high-resistance value was favorably not less than four times as large as the low-resistance value. FIGS. 2(a) and 2(b) show measurement results of the resistance variable characteristics with respect to the number of pulse applications regarding the nonvolatile memory elements using the Hf oxide layers having the oxygen content rates at the point α and the point β, respectively. In measurement at the point α, the voltages of +3.5V and −5V and a pulse width of 100 ns were applied to the upper electrode on the basis of the lower electrode, while in measurement at the point β, the voltages of +1.0V and −1.3V and a pulse width of 100 ns were applied to the upper electrode on the basis of the lower electrode. The operations of the above examples were the operations in the A mode.

As can be seen from FIGS. 2(a) and 2(b), in the elements using the Hf oxide layers having the oxygen content rates at the point α and the point β, the high-resistance value was favorably not less than four times as large as the low-resistance value. Therefore, the composition range in which the oxygen content rate is 46.6 to 62 at %, i.e., the range of x, 0.9≦x≦1.6 in the case where the resistance variable layer is expressed as HfOₓ is a more proper range of the resistance variable layer (oxygen content rate=46.6 at % corresponds to x=0.9, and the oxygen content rate=62 at % corresponds to x=1.6). In the composition analysis according to the RBS method, the analysis value of the oxygen content has a precision of about ±5 at %. Therefore, the composition range of x contains a measurement error associated with this precision, and in actuality, there is a chance that the composition range in which the oxygen content rate is 42˜67 at % is this appropriate composition range.

By setting the composition to HfOx (0.9≦x≦1.6) and by driving (bipolar-driving) the element so that the voltage satisfies V−<V+, the element is able to operate at a high-speed (driven with a pulse width of about 100 ns).

[Resistance Switching of Resistance Variable Element in which Upper and Lower Electrode Materials are Made Different]

Next, research result of resistance variable phenomenon in response to the electric pulses of the structure in which the oxygen-deficient HfOx layer 504 is sandwiched between the lower electrode made of W and the upper electrode 505 made of Al, Ti, Ta, W, Cu, or Pt will described, to confirm whether or not easiness of resistance switching depends on the electrode material. The oxygen content rate of the oxygen-deficient Hf oxide used was set to 61 at % (HfO_{1.56}) which is close to the upper limit of the suitable range of oxygen content rate. The manufacturing method of the element was substantially identical to that described above in the deposition method of the Hf oxide, but is different in that after deposition of the Hf oxide, the element in the middle of the manufacturing process was released to atmosphere, and Al, Ti, Ta, W, Cu, or Pt was deposited in another sputtering device.

TABLE 2

| Sample name | Lower electrode material | Upper electrode material |
|---|---|---|
| A | Pt | Pt |
| B | Pt | Pt |
| C | W | Al |
| D | W | Ti |
| E | W | Hf |
| F | W | Ta |
| G | W | W |
| H | W | Cu |
| I | W | Pt |

Table 2 shows the relationship among the samples C˜I manufactured, the lower electrodes and the upper electrodes.

The samples C˜I were applied with the electric pulses with a predetermined amplitude and a pulse width of 100 nsec and were caused to switch resistance in the B mode and in the A mode. In both of the B mode and the A mode, the amplitude of the voltage for attaining the high-resistance state was larger than the amplitude of the voltage for attaining the low-resistance state, except for a few cases where the resistance switching did not easily occur.

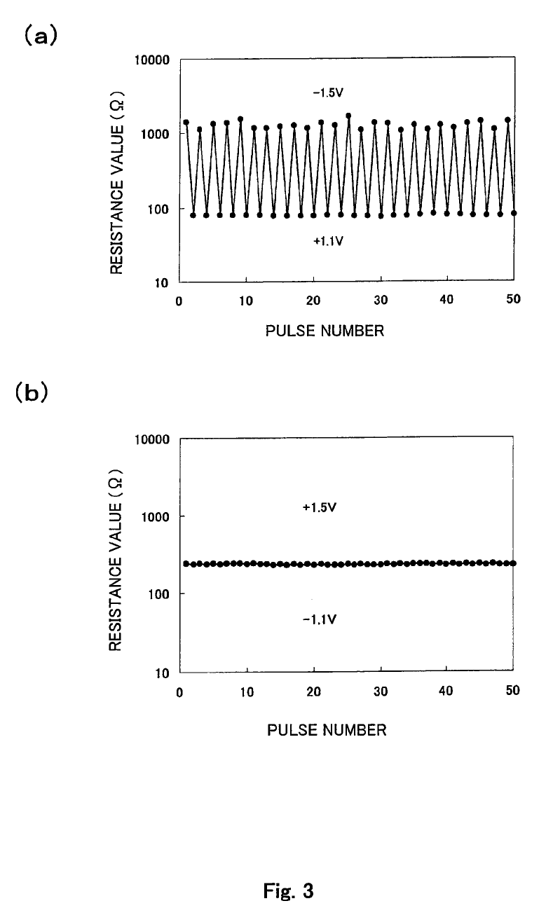

FIGS. 3 to 9 show switching of resistance value of the resistance variable element which occurs when the positive and negative electric pulses are applied alternately to the samples C˜I in the B mode and in the A mode. In these Figures, (a) show the measurement results in the A mode and (b) show the measurement results in the B mode.

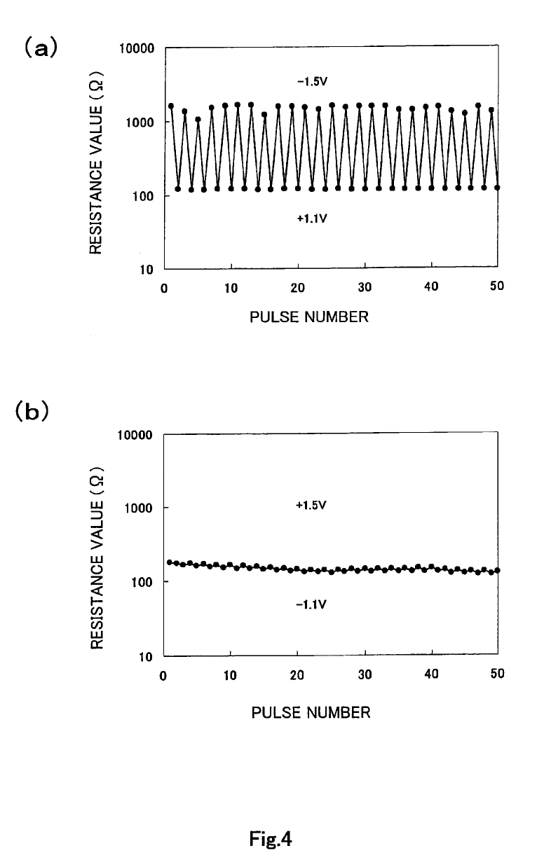

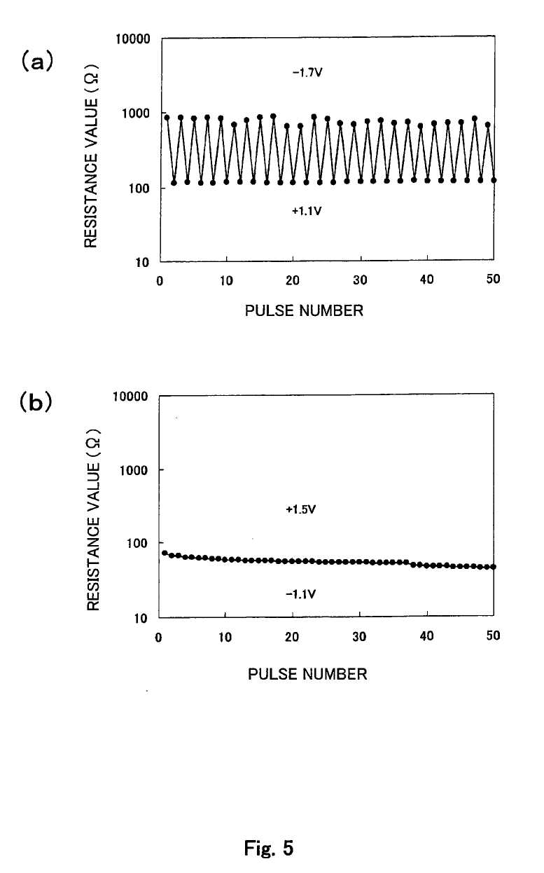

Initially, with reference to the results of the sample C using Al as the upper electrode of FIGS. 3(a) and 3(b), the sample D using Ti as the upper electrode of FIGS. 4(a) and 4(b), and the sample E using Hf as the upper electrode of FIGS. 5(a) and 5(b), resistance switching occurred relatively stably and with a switching magnitude of about a single digit in the A mode, but resistance switching did not substantially occur or did not occur at all in the B mode. From the above result, it may be judged that when the upper electrode is made of Al, Ti, or Hf and the lower electrode is made of W, resistance switching does not occur at the upper electrode side but only at the lower electrode side.

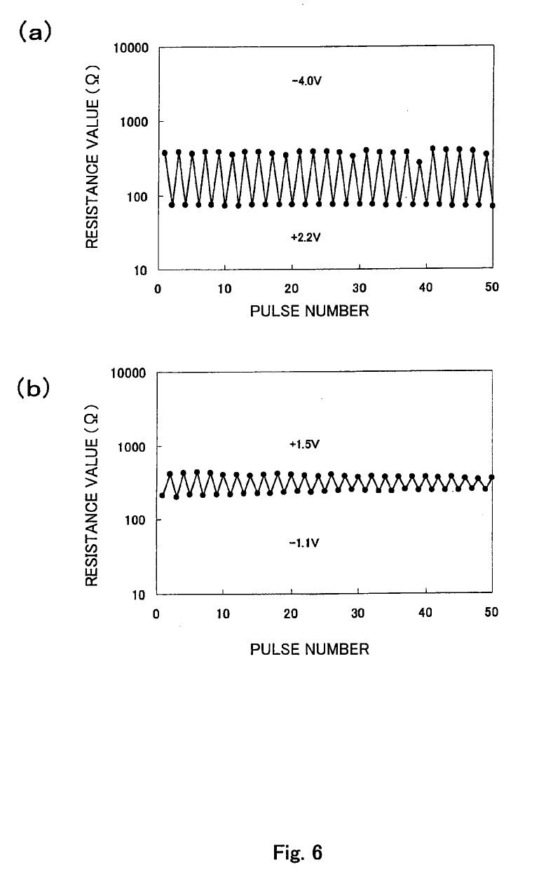

In the sample F using Ta as the upper electrode of FIGS. 6(a) and 6(b), resistance switching occurred relatively stably and with a large width in the A mode, whereas in the B mode, slight resistance switching was observed in an initial stage, the switching magnitude decreased with an increase in the pulse number, and resistance switching did not substantially occur. From the above result, it may be judged that when the upper electrode is made of Ta and the lower electrode is made of W, resistance switching with a small switching magnitude occurs at the upper electrode side, and turns to occur with difficulty with repetitive pulse application at the upper electrode side, but stable resistance switching occurs at the lower electrode side.

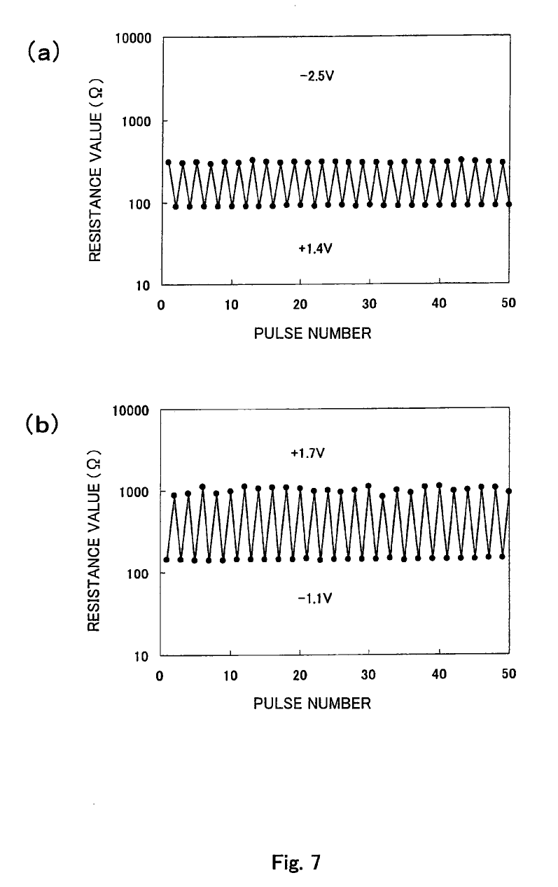

In the sample G using W as the upper electrode of FIGS. 7(a) and 7(b), resistance switching occurred relatively stably in the B mode and in the A mode.

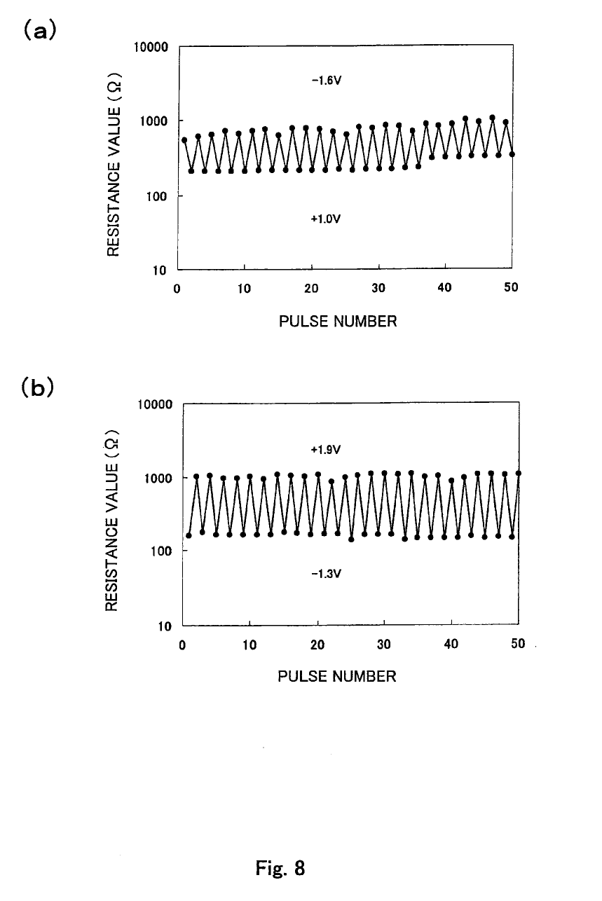

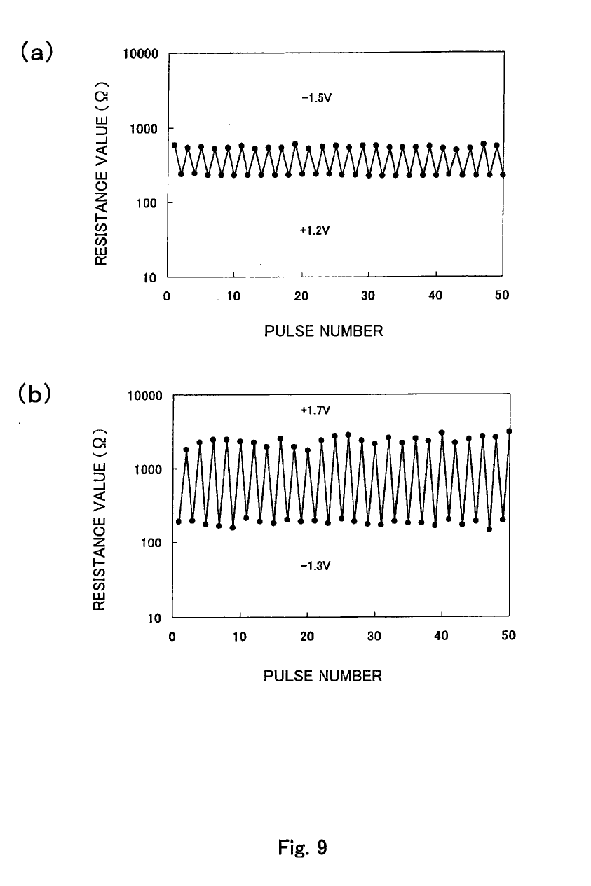

In the sample H using Cu as the upper electrode of FIGS. 8(a) and 8(b), and the sample I using Pt as the upper electrode of FIGS. 9(a) and 9(b), resistance switching occurred relatively stably and with a switching magnitude of about a single digit in the B mode, whereas resistance switching occurred with a small switching magnitude slightly unstably in the A mode. From the above result, it may be judged that when the upper electrode is made of Cu or Pt and the lower electrode is made of W, relatively stable resistance switching occurs at the upper electrode side but unstable resistance switching occurs at the lower electrode side.

Subsequently, consideration to the above results will be given. First, results of FIGS. 3(b) to 9(b) which are obtained by applying the voltage in order to cause resistance switching in the region in the vicinity of the upper electrode 505 (B mode) will be considered. From these results, it is found that there are a material which easily causes resistance switching phenomenon (operates easily) and a material which does not easily cause resistance switching (does not operate easily) for the nonvolatile memory element using the oxygen-deficient Hf oxide. That is, it is apparent that when at least Pt, Cu or W is used as the electrode, resistance switching easily occurs, whereas when Al, Ti or Hf is used as the electrode, resistance switching does not easily occur. It may be considered that these materials basically have a property in which resistance switching does not easily occur.

Subsequently, results of FIGS. 3 to 6 will be considered. In the example shown in FIGS. 3 to 6, the upper electrodes are made of materials (Al, Ti, Hf, Ta) which do not easily cause resistance switching and the lower electrodes are made of the material (W) which easily causes resistance switching. The results shown in FIG. 3(a) to FIG. 6(a) indicate that the resistance variable phenomenon occurs very stably when the upper electrodes are made of Al, Ti, Hf, and Ta. With reference to the results shown in FIG. 3(b) to FIG. 6(b), resistance switching does not substantially occur in the B mode. This may imply an ideal operation of the resistance variable nonvolatile memory element which performs a bipolar operation for causing resistance switching only in the region in the vicinity of one electrode. Although W is used as the electrode at which the operation occurs, in the examples shown in FIG. 3(a) to FIG. 6(a), the electrode material is not limited to this and similar results are expected using the electrodes which easily cause resistance switching, such as Cu or Pt.

From the above, it was discovered that since resistance switching is able to occur at a desired electrode side by forming the structure in which the resistance variable layer is sandwiched between the electrode which easily causes resistance variable phenomenon and the electrode which does not easily cause resistance variable phenomenon, it is possible to manufacture the resistance variable nonvolatile memory element which exhibits a stable bipolar operation without mixing between the upper electrode mode and the lower electrode mode. Regarding the relationship between the applied voltage and the resistance value, an operation occurred, in which the resistance value became high when a positive voltage electric pulse was applied to the electrode which easily causes resistance switching and became low when a negative voltage electric pulse was applied to the electrode which easily causes resistance switching.

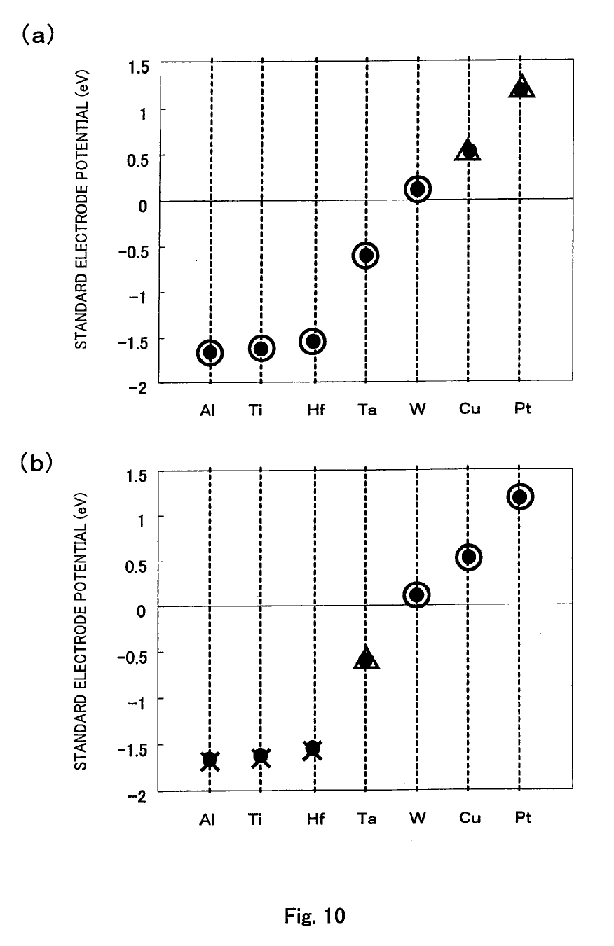

Subsequently, a mechanism for causing resistance switching and material dependency of easiness of resistance switching will be considered a little. FIGS. 10(a) and 10(b) show result of resistance switching in the A mode and result of resistance switching in the B mode, respectively. On a horizontal axis, electrode materials are plotted, while on a vertical axis, standard electrode potentials are plotted. In the Figures, ◯ indicates that resistance switching easily occurred, Δ indicates that resistance switching occurred with a small rate, and X indicates that resistance switching did not occur. As can be seen from FIG. 10(b), resistance switching occurs in a material whose standard electrode potential is higher than that of Hf which is a constituent element of the resistance variable layer and resistance switching does not easily occur in a material whose standard electrode potential is lower. In addition, it is seen that resistance switching occurs more easily as the difference the standard electrode potentials is larger, while the switching occurs more difficultly as the difference is smaller. In general, the standard electrode potential is an indication of easiness of oxidation. When the value of the standard electrode potential is larger, oxidation does not easily occur, whereas when the value is smaller, oxidation occurs more easily. From this fact, it is presumed that the easiness of oxidation plays an important role in the mechanism of the resistance variable phenomenon.

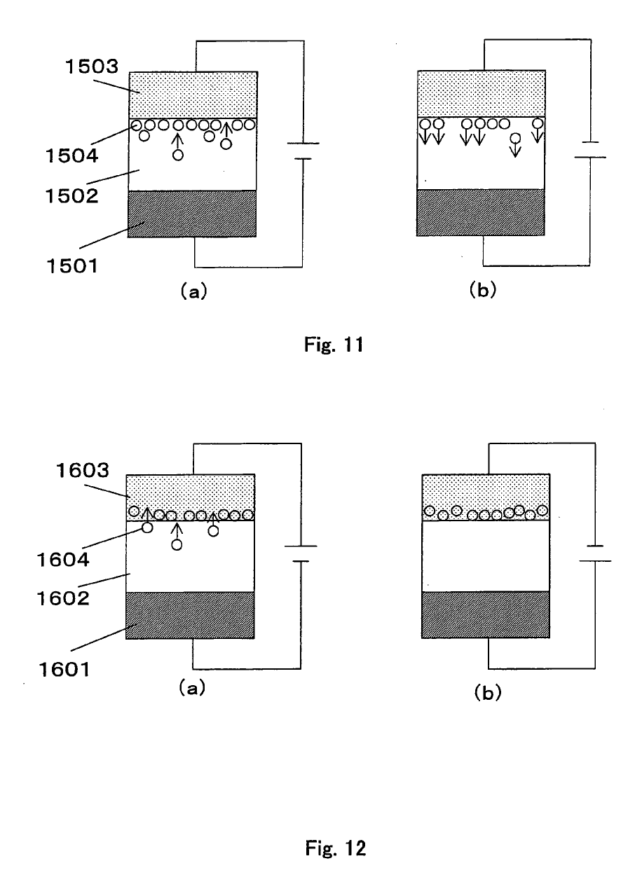

Based on the above result, the mechanism of resistance switching will be described. Initially, a case where the upper electrode is made of a material which easily causes resistance switching (material whose standard electrode potential is high and which is not easily oxidized) will be described with reference to FIG. 11. As shown in FIG. 11(a), in a case where in a resistance variable element including a lower electrode 1501, an oxygen-deficient Hf oxide layer 1502, and an upper electrode 1503 which is made of a material which is oxidized less easily than Hf, a higher voltage is applied to the upper electrode 1603 with respect to the lower electrode 1501, oxygen atoms in the oxygen-deficient Hf oxide are converted into ions, which travel due to an electric field and gather in the vicinity of an interface between the Hf oxide layer 1502 and the upper electrode 1503. However, a metal forming the upper electrode 1503 is oxidized less easily than Hf and therefore oxygen ions 1504 stay at the interface between the oxygen-deficient Hf oxide 1502 and the upper electrode 1503 and are bonded to Hf in the vicinity of the interface to produce an oxygen-deficient Hf oxide with a higher oxygen concentration. Thereby, the element switches to a high-resistance state. As shown in FIG. 11(b), when a higher voltage is applied to the lower electrode 1501, oxygen atoms are converted into oxygen ions again and return to the inside of the oxygen-deficient Hf oxide 1502. Thereby, resistance switches to a low-resistance state.

FIG. 12 shows a case where the upper electrode is made of a material which is oxidized more easily than Hf. As shown in FIG. 12, in a case where in a resistance variable element including a lower electrode 1601, an oxygen-deficient Hf oxide layer 1602, and an upper electrode 1603 which is made of a material which is oxidized more easily than Hf, a higher voltage is applied to the upper electrode 1603 with respect to the lower electrode 1601, oxygen atoms in the oxygen-deficient Hf oxide are converted into ions, which travel due to an electric field and gather in the vicinity of an interface between the Hf oxide layer 1602 and the upper electrode 1603. In this case, since the upper electrode 1603 is oxidized more easily than Hf, oxygen ions 1604 are sucked into the inside of the upper electrode 1603 and are bonded to the material forming the upper electrode 1603. In this case, since a high-resistance layer is not formed at the interface between the oxygen-deficient Hf oxide 1602 and the upper electrode 1603 and the oxygen ions are fewer than the elements forming the upper electrode 1603, the resistance value does not substantially increase, unlike the example shown in FIG. 11. On the other hand, as shown in FIG. 12(b), it may be considered that when a high voltage is applied to the lower electrode 1601, oxygen sucked into the upper electrode 1603 is bonded to the upper electrode material more stably and therefore are less likely to return to the inside of the oxygen-deficient Hf oxide 1602, and the resistance value does not change greatly.

Assuming that the material forming the upper electrode is oxidized as easily as Hf in the examples shown in FIGS. 11 and 12, it may be considered that an intermediate switching of the switching in the above two examples, i.e., slight resistance switching occurs.

As should be understood from the above result, in the nonvolatile memory element using the oxygen-deficient Hf oxide as the resistance variable layer, it is sufficient that the materials with different standard electrode potentials are used for the upper and lower electrodes. This makes it possible to cause resistance switching to occur dominantly in the vicinity of one electrode and attain ideal bipolar resistance switching. In addition, mixing between the upper electrode mode and the lower electrode mode does not occur, and a stable resistance switching operation is achieved. More suitably, a material whose standard electrode potential is higher than that of Hf and has a large standard electrode potential difference with that of Hf may be used as one electrode material and a material whose standard electrode potential is higher than that of Hf and has a small standard electrode potential difference with that of Hf may be used as the other electrode material. More suitably, a material whose standard electrode potential is higher than that of Hf may be used as one electrode material and a material whose standard electrode potential is not higher than that of Hf may be used as the other electrode material.

As should be evident from the above mechanism, the element exhibits an operation in which when a positive voltage electric pulse is applied to the electrode which easily causes resistance switching, the resistance value increases, while when a negative voltage electric pulse is applied to the electrode which easily causes resistance switching, the resistance value decreases.

Although the resistance variable layer is made of the oxygen-deficient Hf oxide in the above-mentioned nonvolatile memory element, the entire of the resistance variable layer need not be made of the oxygen-deficient Hf oxide. It is sufficient that a major resistance variable material is an oxygen-deficient Hf oxide. That is, it is sufficient that the resistance variable layer of the nonvolatile memory element contains the oxygen-deficient Hf oxide. Nonetheless, it is desired that the oxygen-deficient Hf oxide contribute to the resistance switching. In other words, the resistance variable layer may contain impurities and other substances so long as they do not degrade the resistance variable characteristic of the oxygen-deficient Hf oxide. For the reference, documents and technical common sense will be described below.

(Technical Common Sense for Doping Resistance Variable Element)

### 1. International Publication 2005/117021 (Applicant: UNITY Co., Ltd.)

Document 1 discloses an example in which transition metal oxide having a perovskite structure is used as a resistance variable layer in a nonvolatile programmable memory (paragraph 0165) and describes as follows in paragraph 0172.

“Further, vacancies (either anion or cation) can also act to create charge traps. The charge imbalance caused by a vacancy can be compensated by the same mechanisms that compensate for the intentional additions of a dopant. Thus, an oxygen vacancy compensated by 2Cr atoms provides no free carriers, but if there is insufficient Cr for full compensation, oxygen vacancies lead to free electrons” (paragraph 0175 in Translated National Publication Patent Application No. 2007-536680).

That is, the perovskite structure disclosed in the same document is different from the transition metal oxide consisting of two elements, such as the Hf oxide of the present invention, but the resistance variable material made of the transition metal oxide disclosed in the same document makes use of the mechanism of oxygen deficiency (oxygen vacancy), as in the resistance variable material of the present invention.

The same document discloses as follows in paragraph 0199.

“In a particular aspect, doping alters resistivity. For example, application of an electric pulse reversibly changes the resistivity from either a high value to a low value or from a low value to a high value; and doping the materials can modify the magnitude of the difference from the high value to the low value” (paragraph 0202 in Translated National Publication Patent Application No. 2007-536680).

That is, the same document describes that the magnitude of the difference between a high-resistance value and a low-resistance value can be adjusted by doping the transition metal oxide having the resistance variable characteristic.

The same document discloses as follows in paragraph 0200 and paragraph 0201.

“In another aspect, doping alters the amount or magnitude of charge traps or otherwise modifies the ability of the charge traps to capture electrons and thus, improve the data retention capability of the memory plug. In other words, the doping should facilitate electrons tunneling through the memory plug and leaving charge traps during the operation of the memory. In yet another aspect, doping additionally reduces the temperature sensitivity of its resistance. In a further aspect, doping reduces magnetic field dependence.” (paragraph 0203 and paragraph 0204 in Translated National Publication Patent Application No. 2007-536680).

In these paragraphs, it is described that a characteristic different from a basic resistance variable characteristic is improved by further doping the transition metal oxide having the resistance variable characteristic.

### 2. Translated National Publication Patent Application No. 2002-537627 (Applicant: Ibm Co., Ltd.)

Document 2 discloses an example in which a perovskite and associated compound are used as a resistance variable layer in a semiconductor memory such as a nonvolatile memory (paragraph 0016 and paragraph 0017). As a specific example of the associated compound, described in paragraph 0027 is that “combinations of x, y and z in a case where x=1, y=1, z=1, and index number x or y is defined as O indicate typical substances such as BeO, MgO, BaO, CaO, . . . NiO, MnO, CoO, ZnO, etc. Or, . . . (an omission) . . . combinations of index numbers x, y, and z in a case where n=1 and index number x or y is defined as O indicate substances such as TiO₂, VO₂, MnO₂, GeO₂, PrO₂, and SnO₂. In a case where N=2, the combinations indicate substances such as Al₂O₃, Ce₂O₂, Nd₂O₃, Ti₂O₃, Sc₂O₃, and La₂O₃. Or, . . . (an omission) the combinations indicate typical substances such as Nb₂O₅, and Ta₂O₅”.

That is, the same document discloses the resistance variable element using the transition metal oxide consisting of two elements as in the present invention, as well as the transition metal oxide having the perovskite structure.

The same document describes as follows in paragraph 0017.

“Microelectronic device can be designed to include between electrodes a region with a switchable ohmic resistance which is formed by a material containing compounds Ax, and By and oxygen Oz. The ohmic resistance of the region is inversely switchable between different states by applying different voltage pulses. Different voltage pulses cause the associated different states. With a proper dopant amount of substances, switching is improved and therefore the microelectronic device can be controlled. As a result, reliability is achieved.”

That is, the document describes that by properly doping with respect to the original resistance variable characteristic, switching is improved. “The material containing compounds Ax, and By and oxygen Oz” includes transition metal oxide consisting of two elements in view of the recitation of [0027]. This document discloses that switching is improved by properly doping in the resistance variable element using the transition metal oxide consisting of two elements.

3. Japanese Laid-Open Patent Application Publication No. 2006-279042 (applicant: Samsung Electronics Co., Ltd.)

Document 3 discloses a nonvolatile memory including a resistance memory element which is switchable reversibly between two different resistance states in response to a voltage (paragraph 0002). Document 3 discloses as follows in paragraph 0026.

“For example, when the resistance memory element is expressed as MOx, and metal M is Ni, Co, Zn or Cu, x indicating a content ratio of oxygen atoms O has a range from 0.5 to 0.99 (0.5≦x≦0.99). Differently from this fact, when the metal M is Hf, Zr, Ti or Cr, x indicating a content ratio of oxygen atoms O has a range from 1.0 to 1.98 (1.0≦x≦1.98). When the metal M is Fe, x indicating a content ratio of oxygen atoms O has a range from 0.75 to 1.485. When the metal M is Nb, x indicating a content ratio of oxygen atoms O has a range from 1.25 to 2.475.

That is, as in the present invention, Document 3 discloses a resistance variable element using a transition metal oxide having oxygen deficiency and consisting of two elements.

Furthermore, Document 3 discloses as follows in paragraph 0016.

“The transition metal oxide may contain impurities such as lithium, calcium, or lanthanum.”

In other words, some impurities may be added to the resistance variable element comprising transition metal oxide having oxygen deficiency and consisting of two elements as in the present invention.

Consideration to the above recitation of Document 3 will be given in greater detail.

According to the recitation, the material forming the resistance memory element contains Fe₃O₄ (X=1.33). According to recitation in Rikagaku jiten (fourth edition, Iwanami shoten 1987), Fe₃O₄ (triiron tetroxide) has a following feature.

1) Crystal structure→inverse spinel structure (different from perovskite structure)
2) Resistivity→4×10⁻³ Ω·cm (like semiconductor at a room temperature and is not an insulator).

The resistivity of metal iron is 9.71×10⁻⁶Ωcm. Therefore, the resistivity of Fe₃O₄ corresponds to 1/400 of metal Fe.

That is, according to the recitation of Document 3 and Rikagakujiten, transition metal oxide which is not an insulator but has electric conductivity and has a non-perovskite structure (consisting of two elements) has a resistance variable characteristic. These apply to the invention of the subject application.

Document 1 mentioned previously illustrates an example using the transition metal oxide having a perovskite structure and is different in this respect from the invention of the subject application. However, Document 2 or Document 3 discloses that impurities are added to the conductive transition metal oxide having a non-perovskite structure and exhibiting a resistance variable characteristic and the resulting conductive transition metal oxide is used as the resistance variable element.

### 4. Japanese Laid-Open Patent Application Publication No. 2006-165553 (Applicant: Samsung Electronics Co., Ltd.)

Document 4 discloses an invention relating to a phase-change memory having nonvolatility (paragraph 0003). Further, Document 4 discloses as follows in paragraph 0016.

“In the embodiment of the present invention described above, the phase change material may be formed of transition metal oxide having plural resistance states. For example, the phase change material may be formed of at least one substance selected from a group consisting of NiO, TiO₂, HfO, Nb₂O₅, ZnO, WO₃, and CoO or GST (Ge₂Sb₂Te₅), or PCMO (PrₓCa₁₋ₓMnO₃)”.

That is, as in the present invention, Document 2 and Document 3, Document 4 discloses that the resistance variable element can be formed using the resistance variable material made of the transition metal oxide consisting of two elements.

The same document discloses as follows in paragraph 0026.

“Also, nano particles prepared to adjust the physical property of phase-change nano particles of the phase change material layer may be doped with nitrogen, silicon, etc.”

In other words, the characteristic can be controlled by doping the transition metal oxide which is a major material.

As described above, Document 1 to Document 4 disclose examples in which the resistance variable element is made of only the transition metal oxide having the resistance variable characteristic and consisting of two elements, and the resistance variable element is made of transition metal oxide having oxygen deficiency and the resistance variable characteristic, and examples in which the above basic structures are doped.

That is, it may be a technical common sense that the resistance variable element having the resistance variable characteristic because of a major material (transition metal oxide) may be doped for the purpose of control, adjustment, improvement, etc.

(Technical Common Sense that Unintended Impurities are Mixed Due to Sputtering)

In the above description, the sputtering process is used to deposit the Hf oxide layer as the resistance variable layer. Description will be given below of a technical common sense that unintended impurities are mixed into the layer by using the sputtering process.

5. “SEMICONDUCTOR MATERIALS AND PROCESS TECHNOLOGY HANDBOOK” (McGUIRE published in 1988)

Document 5 describes that undesired gas is generated from a substrate, a chamber wall or the like by using the sputtering process (page 333 line 25˜29).

6. “Measure for various problems and troubles in technique for forming various thin films-total technique document −(Keiei Kaihatsu Center Publishing Department, published on May 20, Showa 60).

Document 6 describes that quality of the film to be deposited is degraded by contamination in a vacuum device, such as residual impurity gas or gas release from a vacuum container wall (page 324 right column line 1˜15).

7. “Integrated circuit handbook” (Maruzen Co., Ltd., published on November 25, showa 43)

Document 7 describes that vapor deposition is not always conducted in vacuum but a thin film to be deposited is greatly affected by various residual gases in a commercially available vapor deposition apparatus (page 151 line 3˜page 152 line 3, page 153 line 1˜2).

From the above recitation, it is a technical common sense that unintended impurities are mixed into the film to be deposited by using the sputtering process in a manufacturing line.

The above cited document describing the technical common sense at the time the present application was filed describes an example in which the resistance variable element is made of the transition metal oxide having the resistance variable characteristic and having oxygen deficiency and an example in which the structure is doped for addition of other material. The former example is identical to the example of the embodiment and is a basic structure. The latter example is an application making the use of the basic structure. This means that in a technical field of the resistance variable element using the transition metal oxide, it is well-known that its characteristic is controlled or the like by adding other materials to the basic structure.

Also, it is well-known that unintended impurities are mixed into the film to be deposited in the manufacturing line.

According to the recitation of the above document, it is a technical common sense that other substances are added to the major constituents of the resistance variable layer, and other substances are mixed into the resistance variable layer as a result of the manufacturing process.

In light of the above, obviously, it is sufficient that the resistance variable layer contains the oxygen-deficient Hf oxide in the nonvolatile memory element of the present invention.

A nonvolatile memory apparatus of the present invention comprises an electric pulse application device, and a resistance variable nonvolatile memory element which comprises the above mentioned oxygen-deficient Hf oxide and performs the bipolar operation, wherein the electric pulse application device is configured to apply positive and negative electric signals to the nonvolatile memory element to reversibly switch the resistance value between the first electrode and the second electrode of the nonvolatile memory element. To be specific, the electric pulse application device is configured to apply an electric pulse with a first polarity (e.g., positive polarity) to the second electrode on the basis of the first electrode to switch the resistance value between the first and second electrodes to a first resistance value (e.g., switch the nonvolatile memory element to a high-resistance state) and apply an electric pulse with a second polarity (e.g., negative polarity) to the second electrode on the basis of the first electrode to switch the resistance value between the first and second electrodes to a second resistance value (e.g., switch the nonvolatile memory element to a low-resistance state).

A method of writing data to the nonvolatile memory element of the present invention is a method of writing data to the resistance variable nonvolatile memory element which comprises the above mentioned oxygen-deficient Hf oxide and performs the bipolar operation, comprising applying positive and negative electric signals between the first electrode and the second electrode of the nonvolatile memory element to reversibly switch the resistance value between the first and second electrodes of the nonvolatile memory element. To be specific, the electric pulse with the first polarity (e.g., positive polarity) is applied to the second electrode on the basis of the first electrode to switch the resistance value between the first and second electrodes to the first resistance value (e.g., switch the nonvolatile memory element to a high-resistance state) and the electric pulse with the second polarity (e.g., negative polarity) is applied to the second electrode on the basis of the first electrode to switch the resistance value between the first and second electrodes to a second resistance value (e.g., switch the nonvolatile memory element to a low-resistance state).

Numeral modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

### INDUSTRIAL APPLICABILITY

A nonvolatile memory element and a nonvolatile memory apparatus of the present invention are capable of high-speed operation and have a stable rewrite characteristic. They are useful as nonvolatile memory elements, and the like which are used in various electronic devices such as digital home electric appliances, memory cards, cellular phones, and personal computers.

1. A nonvolatile memory element comprising a first electrode, a second electrode, and a resistance variable layer disposed between the first electrode and the second electrode, a resistance value between the first electrode and the second electrode being switchable reversibly in response to positive and negative electric signals applied between the first electrode and the second electrode;
wherein the resistance variable layer includes an oxygen-deficient hafnium oxide;
wherein the first electrode and the second electrode comprise elements which are different from each other; and
wherein a standard electrode potential V1 of an element forming the first electrode, a standard electrode potential V2 of an element forming the second electrode and a standard electrode potential V0 of hafnium satisfy a relationship of V1<V2 and V0<V2.

2. A nonvolatile memory element comprising a first electrode, a second electrode, and a resistance variable layer disposed between the first electrode and the second electrode, a resistance value between the first electrode and the second electrode being switchable reversibly in response to positive and negative electric signals applied between the first electrode and the second electrode;
wherein the resistance variable layer includes an oxygen-deficient hafnium oxide;
wherein the first electrode and the second electrode comprise elements which are different from each other; and
wherein a standard electrode potential V1 of an element forming the first electrode, a standard electrode potential V2 of an element forming the second electrode and a standard electrode potential V0 of hafnium satisfy a relationship of V1≦V0<V2.

3. The nonvolatile memory element according to claim 2, wherein the first electrode is selected from a group consisting of Al, Ti, and Hf and the second electrode is selected from a group consisting of W, Cu, and Pt.

4. A nonvolatile memory element comprising a first electrode, a second electrode, and a resistance variable layer disposed between the first electrode and the second electrode, a resistance value between the first electrode and the second electrode being switchable reversibly in response to positive and negative electric signals applied between the first electrode and the second electrode;
wherein the resistance variable layer includes an oxygen-deficient hafnium oxide;
wherein the first electrode and the second electrode comprise elements which are different from each other; and
wherein a standard electrode potential V1 of an element forming the first electrode, a standard electrode potential V2 of an element forming the second electrode and a standard electrode potential V0 of hafnium satisfy a relationship of V0<V1<V2.

5. The nonvolatile memory element according to claim 4, wherein the first electrode is made of W and the second electrode is selected from a group consisting of Cu and Pt.

6. The nonvolatile memory element according to any one of claims 1 to 6, wherein the oxygen-deficient hafnium oxide is expressed as a chemical formula HfOₓ (0.9≦x≦1.6).

7. A method of driving the nonvolatile memory element according to any one of claims 1 to 6, wherein the positive and negative electric signals are a positive electric signal with an amplitude V+ which is applied to the second electrode on the basis of the first electrode and a negative electric signal with an amplitude V− which is applied to the second electrode on the basis of the first electrode, respectively, and V+ and V− satisfy a relationship of V−<V+; and wherein the resistance value between the first electrode and the second electrode increases in response to the positive electric signal and decreases in response to the negative electric signal.

8. A nonvolatile memory apparatus comprising:
a nonvolatile memory element including a first electrode, a second electrode, and a resistance variable layer disposed between the first electrode and the second electrode, a resistance value between the first electrode and the second electrode being switchable reversibly in response to positive and negative electric signals applied between the first electrode and the second electrode; wherein the resistance variable layer includes an oxygen-deficient hafnium oxide; wherein the first electrode and the second electrode comprise elements which are different from each other; and wherein a standard electrode potential V1 of an element forming the first electrode, a standard electrode potential V2 of an element forming the second electrode and a standard electrode potential V0 of hafnium satisfy a relationship of V1<V2 and V0<V2; and
an electric pulse application device;
wherein the electric pulse application device is configured to apply the positive and negative electric signals to the nonvolatile memory element to reversibly switch the resistance value between the first electrode and the second electrode of the nonvolatile memory element.

9. A method of writing data to a nonvolatile memory element including a first electrode, a second electrode, and a resistance variable layer disposed between the first electrode and the second electrode, a resistance value between the first electrode and the second electrode being switchable reversibly in response to positive and negative electric signals applied between the first electrode and the second electrode; wherein the resistance variable layer includes an oxygen-deficient hafnium oxide; wherein the first electrode and the second electrode comprise elements which are different from each other; and wherein a standard electrode potential V1 of an element forming the first electrode, a standard electrode potential V2 of an element forming the second electrode and a standard electrode potential V0 of hafnium satisfy a relationship of V1<V2 and V0<V2; the method comprising:
applying the positive and negative electric signals between the first electrode and the second electrode of the nonvolatile memory element to reversibly switch the resistance value between the first electrode and the second electrode of the nonvolatile memory element.
